(19) United States
(12) Patent Application Publication
(10) Pub. No.: US 2005/0193951 A1
(43) Pub. Date: Sep. 8, 2005

(54) Plasma processing apparatus

(76) Inventors: Muneo Furuse, Kudamatsu-shi (JP); Masanori Kadotani, Kudamatsu-shi (JP); Masatsugu Arai, Ibaraki-ken (JP); Hiroho Kitada, Kudamatsu-shi (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 10/793,782

(22) Filed: Mar. 8, 2004

(51) Int. Cl. C23C 16/00; C23F 1/00

(52) U.S. Cl. 118/728; 156/345.51

(57) ABSTRACT

The object of the present invention is to provide a plasma processing apparatus capable of processing a substrate stably for a long period of time. The plasma processing apparatus has a substrate holder disposed in a processing chamber and an electrode cover for protecting a support stage of said substrate holder, for processing a wafer placed on said support stage using a plasma generated in the processing chamber, wherein at least a surface of said electrode cover that is positioned directly below an edge of the wafer, or at least a surface of said electrode cover that comes into contact with plasma, is coated with a material having resistance to plasma and comprising Y₂O₃, Yb₂O₃ or YF₃, or a mixture thereof, as its main component.

### FIELD OF THE INVENTION

The present invention relates to a plasma processing apparatus to be used in micromachining of a semiconductor manufacturing process and the like, and especially relates to a plasma processing apparatus that is capable of suppressing the amount of contaminants to be discharged from the support stage, and that is capable of carrying out stable micromachining for a long period of time.

### DESCRIPTION OF THE RELATED ART

Conventionally, plasma processing apparatuses such as plasma CVD apparatuses and plasma etching apparatuses are used widely as semiconductor manufacturing apparatuses, for manufacturing semiconductor devices by processing plate members to be processed such as silicon wafers (hereinafter referred to as wafers). Recently, along with the enhancement in the integration of devices, the circuit patterns have become more and more refined, and the required accuracy for the dimension of the processing by the plasma processing apparatuses has become very strict. Further, along with the diversification in the materials constituting the device, the etching recipes have become complex, and the stability of the processes for long-term mass production has become a serious problem. For example, in a plasma processing apparatus, plasmas generated with reactive gases such as fluoride, chloride and bromide are used, so the surface of the walls and the support stage (electrostatic chucking electrode) of the processing chamber are eroded both chemically and physically.

Especially, the support stage is eroded significantly since high frequency is applied thereto. When the eroded components are released into plasma, the chemical composition and the high-frequency transmission property within the processing chamber are varied gradually, and in some cases, it becomes impossible to perform a long-term stable processing. Further, the material constituting the eroded wall surface of the processing chamber may chemically react with the active radicals in the plasma, and may cause deposits to adhere on the inner walls of the chamber. The thickness of deposits adhered to the inner walls increases through repeated etching, and in the worst case, the deposits may fall from the walls onto the wafer, creating defective products.

In order to cope with this problem, according to a typical solution, the surface of the inner wall of the processing chamber and the members therein such as the stage are subjected to an anodization treatment (so-called an alumite treatment) that provides high stability to chemical reaction (the thickness of the alumite being 20 micrometers in general). Further, a high-purity sintered alumina is used widely as a material having resistance to plasma. However, it is one of the recent important challenges to cut down aluminum contamination. Therefore, attempts have been made to coat materials other than alumina having resistance to plasma. For example, according to Japanese patent application laid-open No. 2002-252209 (patent reference 1), an yttrium fluoride (YF₃) is disposed on the surface of the member disposed in the processing chamber, or sintered yttrium fluoride is used as material for forming the member.

Furthermore, Japanese Patent No. 3426825 (patent reference 2) discloses coating at least the surface of the inner walls of the processing chamber of the plasma processing apparatus with one element of or a compound composed of elements of group 2A of the periodic table.

Patent reference 1: JP Application Laid-Open No. 2002-252209

Patent reference 2: JP No. 3426825

According to the prior art, the alumite material that has been used widely did not have sufficient resistance to plasma to ensure stable processing to be performed for a long period of time. Further, it has been pointed out that the aluminum etched during processing from the alumite material in the chamber causes contaminants to adhere to the surface of the semiconductor wafer or object being processed.

Furthermore, the arts disclosed in patent references 1 and 2 may be effective from the viewpoint of resistance to plasma, but they lack considerations on heat resistance, durability, long lifetime and mass fabrication property of the members in the chamber. Therefore, it cannot be said that the disclosed arts draw out the effects of the plasma-resistant material sufficiently.

For example, according to the arts disclosed in references 1 and 2, the unevenness or bias of potentials of the plasma with respect to the substrate or semiconductor wafer being chucked onto the electrode on the substrate holder causes a specific portion to be subjected to greater plasma injection than the other portions, and the specific portion is chipped thereby. In other words, the portion of a member subjected to concentrated plasma injection greatly affects the timing of replacement of the member, and as a result, affects the operation efficiency of the apparatus, and causes the member to be replaced even if the other portions of the member are still not required to be replaced. The arts disclosed in patent references 1 and 2 do not consider this problem.

Moreover, according to the above-mentioned prior arts, the design of the member disposed in the processing chamber and exposed to plasma was not determined after sufficient consideration of the deformation of the member exposed to plasma.

Further, the above-mentioned prior arts lack sufficient consideration on the appropriate structure of the processing chamber for facilitating the operation for attaching a member having resistance to plasma to the interior of the processing chamber.

### SUMMARY OF THE INVENTION

The object of the present invention is to provide a plasma processing apparatus capable of processing a substrate in a stable manner for a long period of time.

The present invention provides a plasma processing apparatus comprising a substrate holder disposed in a processing chamber and an electrode cover for protecting a support stage of said substrate holder, for processing a wafer placed on said support stage using a plasma generated in the processing chamber; wherein at least a surface of the electrode cover that is positioned directly below an edge of the wafer, or at least a surface of said electrode cover that comes into contact with plasma, is coated with a material having resistance to plasma and comprising Y₂O₃, Yb₂O₃ or YF₃, or a mixture thereof, as its main component.

According further to the plasma processing apparatus of the present invention, the coating having resistance to plasma applied to a portion directly below the edge of the wafer on the surface of the electrode cover is greater in thickness than the coating having resistance to plasma applied to other portions.

### BRIEF DESCRIPTION OF THE DRAWINGS

FIG. 1 is a cross-sectional view showing a plasma processing apparatus according to one embodiment of the present invention;

FIG. 2 is an oblique perspective view showing in partial cross-section the electrostatic chucking electrode according to one embodiment of the present invention;

FIG. 3 is an enlarged view of an electrode cover according to one embodiment of the present invention;

FIG. 4 is a graph showing the amount of chipping of the electrode cover according to one embodiment of the present invention;

FIG. 5 is a view showing the mechanism of how the chipping of the electrode cover surface occurs;

FIG. 6 is an enlarged view of the electrode cover coated with a material having resistance to plasma according to one embodiment of the present invention;

FIG. 7 is a drawing explaining the spray coating method according to one embodiment of the present invention;

FIG. 8 is an enlarged view showing an electrode cover having an electrode cover ring made of a material having resistance to plasma according to one embodiment of the present invention;

FIG. 9 is a chart comparing the etching rate in chlorine plasma of alumite, Al₂O₃ formed by sintering, and Al₂O₃, Yb₂O₃, Y₂O₃ and YF₃ formed by spraying;

FIG. 10 is a graph showing the relationship between the RF power of an electrostatic chucking electrode and the etching rate of alumite;

FIG. 11 is an explanatory view showing a step for regenerating the electrode cover according to one embodiment of the present invention;

FIG. 12 is an explanatory view showing a step for regenerating the electrode cover according to one embodiment of the present invention; and

FIG. 13 is an explanatory view showing a step for regenerating the electrode cover according to one embodiment of the present invention.

### DETAILED DESCRIPTION OF THE PREFERRED EMBODIMENT

Now, the preferred embodiments of the plasma processing apparatus according to the present invention will be described in detail with reference to the drawings.

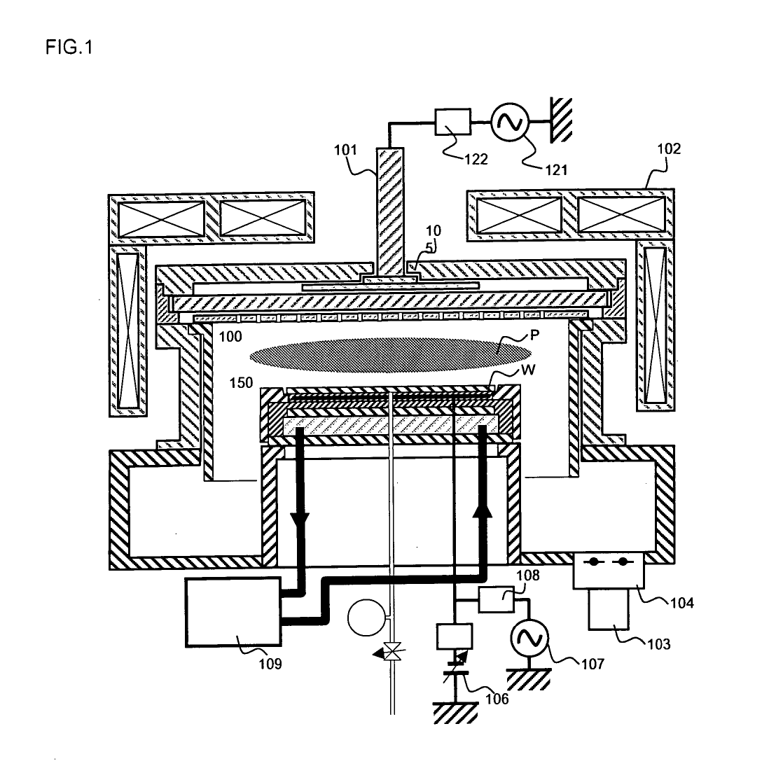

FIG. 1 is a cross-sectional view of a plasma processing apparatus according to one embodiment of the present invention. The plasma processing apparatus illustrated in FIG. 1 is equipped with a processing chamber 100, an antenna 101 disposed above the processing chamber 100 for radiating electromagnetic waves, and a support stage (substrate holder) 150 disposed at the lower area thereof for mounting a substrate to be processed such as a semiconductor wafer W. The antenna 101 is supported on a housing 105 that constitutes a portion of a vacuum container, and the antenna 101 is disposed substantially parallel to and in confronting relation with the support stage 150.

A magnetic field forming means 102 composed of an electromagnetic coil and a yoke, for example, is disposed around the processing chamber 100. The support stage 150 is a member generally so-called an electrostatic chucking electrode.

The processing chamber 100 is a vacuum container capable of realizing a vacuum with a pressure of 1/10000 Pa through an evacuation system 103. The processing gas used to perform processes such as etching and film deposition of the substrate is supplied from a gas supply means not shown into the processing chamber 100 with a determined flow rate and mixture ratio, and the pressure within the processing chamber 100 is controlled through the evacuation system 103 and an evacuation control means 104. According to the present type of plasma processing apparatuses, in general, the processing pressure during etching is controlled typically within the range of 0.1 Pa to 10 Pa.

An antenna power supply 121 is connected to the antenna 101 via a matching circuit 122. The antenna power supply 121 is for supplying power with a frequency in the UHF band, within the range of 300 MHz to 1 GHz, and according to the present embodiment, the frequency of the antenna power supply 121 is set to 450 MHz. A high-voltage power supply 106 for electrostatic chucking and a bias power supply 107 for supplying bias power within the range of 200 kHz to 13.56 MHz, for example, are connected to the electrostatic chucking electrode 150 respectively via a matching circuit 108. Further, a temperature control unit 109 for controlling the temperature is connected to the electrostatic chucking electrode 150. According to the present embodiment, the frequency of the bias power supply 107 is set. to 2 MHz.

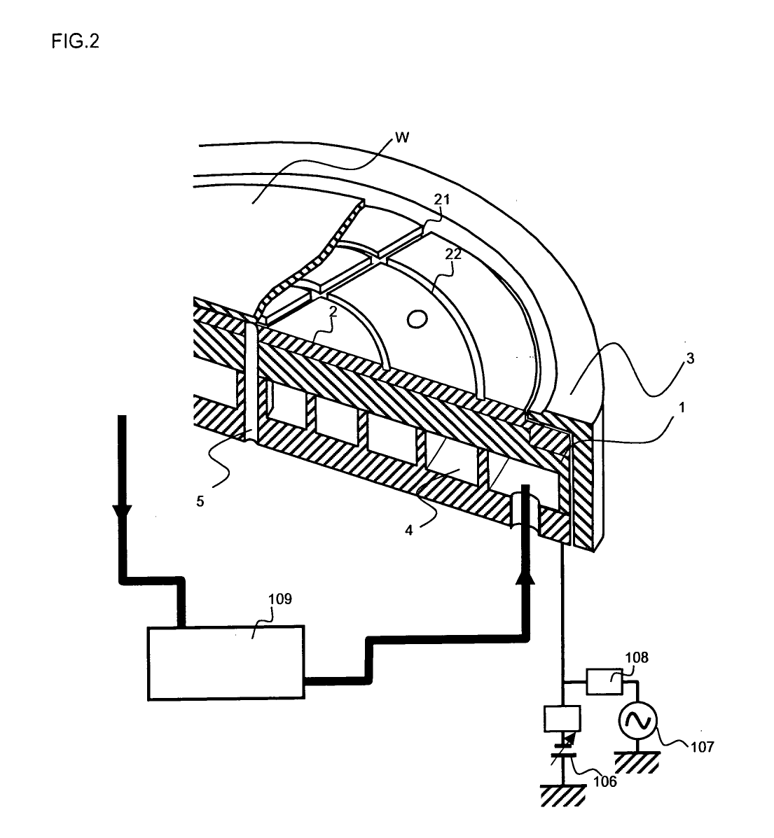

FIG. 2 is a perspective view showing the electrostatic chucking electrode in partial cross-section that is utilized as a support stage 150 for supporting a semiconductor wafer W in the plasma processing apparatus. With reference to the drawing, the structure of the electrostatic chucking electrode 150 will be described in detail. As illustrated in FIG. 2, the electrostatic chucking electrode 150 is composed of an electrode block 1 made of aluminum, a dielectric film 2, and an electrode cover 3 made of alumina. A passage 4 through which circulates a refrigerant supplied thereto with a determined temperature from a temperature control unit 109 is formed within the electrode block 1. The electrode cover 3 made of alumina is a cover for protecting the dielectric film 2. The electrostatic chucking electrode 150 is designed to have a diameter size of 340 mm and an overall thickness of 40 mm, if a semiconductor wafer W of 12 inches (diameter of 300 mm) is to be processed. A high voltage power supply 106 and a bias power supply 107 are connected to the electrode block 1. The dielectric film 2 is provided with a linear slit 21 extending radially and communicated with a gas introduction hole 5, and plural concentric slits 22 communicated therewith, as shown in FIG. 2. A He gas for conducting heat is introduced through the gas introduction hole 5, and the He gas is filled to the back surface of the semiconductor wafer W with an even pressure (normally around 1000 Pa) via the slits. The dielectric film according to the present embodiment is constructed of an alumina ceramics with a thickness of 0.1 mm formed via spray coating, but the material and thickness of the dielectric film 2 is not limited to this embodiment, and for example, in the case of a synthetic resin material, the thickness can be selected within the range of 0.1 mm to a several mm.

The plasma processing apparatus of the present embodiment is constructed as described above. Now, the actual processes for carrying out etching of silicon or the like using this plasma etching apparatus will be described.

In FIG. 1, at first, the semiconductor wafer W being the object of processing is transferred into the processing chamber 100 via a substrate transfer mechanism not shown, and is mounted and chucked onto an electrostatic chucking electrode 150. If necessary, the height of the electrostatic chucking electrode 150 is adjusted to form a predetermined gap. Then, the gas required to carry out the etching process of the semiconductor wafer W, such as chlorine, hydrogen bromide and oxygen, are supplied from a gas supply means not shown into the chamber 100 with a given flow rate and mixture ratio. Simultaneously, the processing chamber 100 is controlled to a given processing pressure via an evacuation system 103 and an exhaust control means 104. Next, an antenna power supply 121 supplies a power of 450 MHz to the antenna 101 so as to radiate electromagnetic waves from the antenna. Then, by the interaction between a substantially parallel magnetic field of 160 gauss formed within the processing chamber 100 by a magnetic field forming means 102 (ECR magnetic field intensity corresponding to 450 MHz) a plasma P is generated efficiently within the processing chamber 100, by which the processing gas is dissociated to create ions and radicals. By controlling the bias power from the bias power supply 107 of the electrostatic chucking electrode 150, the energy and the composition ratio of ions and radicals in the plasma are controlled, and while controlling the temperature of the semiconductor wafer W, the etching of the wafer W is carried out. Then, when the etching process is terminated, the supply of processing gas, power and magnetic field are stopped, and the etching process is completed.

According to the present embodiment, the plasma processing apparatus of the present invention is applied to an UHF-type apparatus, but the invention can also be applied to other types of plasma processing apparatuses.

According to the plasma processing apparatus described in the present embodiment, chipping of the portion directly below the edge of the wafer of the electrode cover 3 made of alumina progresses as the number of processed wafers increases. The status of chipping will be described in detail.

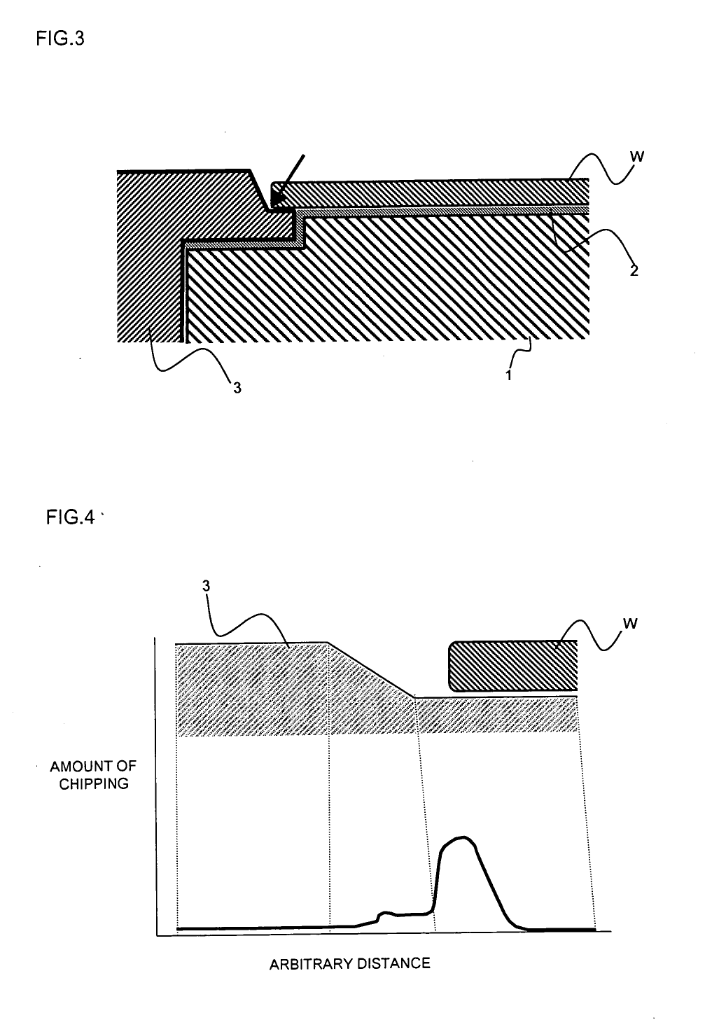

FIG. 3 illustrates the status of chipping of the electrode cover 3 according to the present embodiment. As shown, the electrode cover 3, which is a sintered body of alumina (Al₂O₃), has the area shown by the arrow of FIG. 3 (directly below the edge of wafer W) etched or chipped significantly as the number of wafers W being processed increases. FIG. 4 shows the distribution of the amount of chipping of the electrode cover surface. As shown, the portion directly below the edge of the wafer W is chipped significantly, and the value reaches several times the chipped amount of other portions on the surface. Upon observing the chipped surface closely, the surface was smooth and no reaction products could be confirmed. That is, since high frequencies are applied to the electrostatic chucking electrode 150, sputtering is caused by the applied high frequencies, and the portion directly below the edge of the wafer W is chipped. The intense erosion of the area directly below the edge of the wafer W is considered to be caused by the combination of following three causes. FIG. 5 shows the causes of chipping of the electrode cover surface in frame format. As shown, it is considered that the first cause is the concentration of the electric field at the edge of the wafer created by the application of high frequencies, the second cause is the lens effect caused by the curvature of the ion sheath formed to the electrode cover surface, and the third cause is the ions being concentrated by the bouncing of ions entering the tapered portion of the electrode cover 3. The ion sheath is an electric field created by the ions being left behind from the electrons moving at high speed in the plasma.

As explained, the electrode cover 3 serving as the protective cover for the electrostatic chucking electrode 150 is subjected to chipping by the ions entering the cover during plasma etching. When the electrode cover 3 directly below the wafer is chipped intensely, the distribution of the high frequencies being applied to the electrostatic chucking electrode 150 is varied especially at the wafer edge, and as a result, the etching properties may be varied. Thus, in plasma processing apparatuses, the electrode cover 3 having reached a determined amount of chipping is replaced frequently. Therefore, if the frequency of replacement is high, the operation efficiency of the apparatus is deteriorated, and the cost for replacement members is increased. Further, along with the recent refinement of the devices, it has become a important task to reduce the amount of aluminum being sputtered from the electrode cover 3.

Therefore, the electrode cover 3 illustrated in the present embodiment is designed to reduce the chipping caused by sputtering and to enable regeneration thereof.

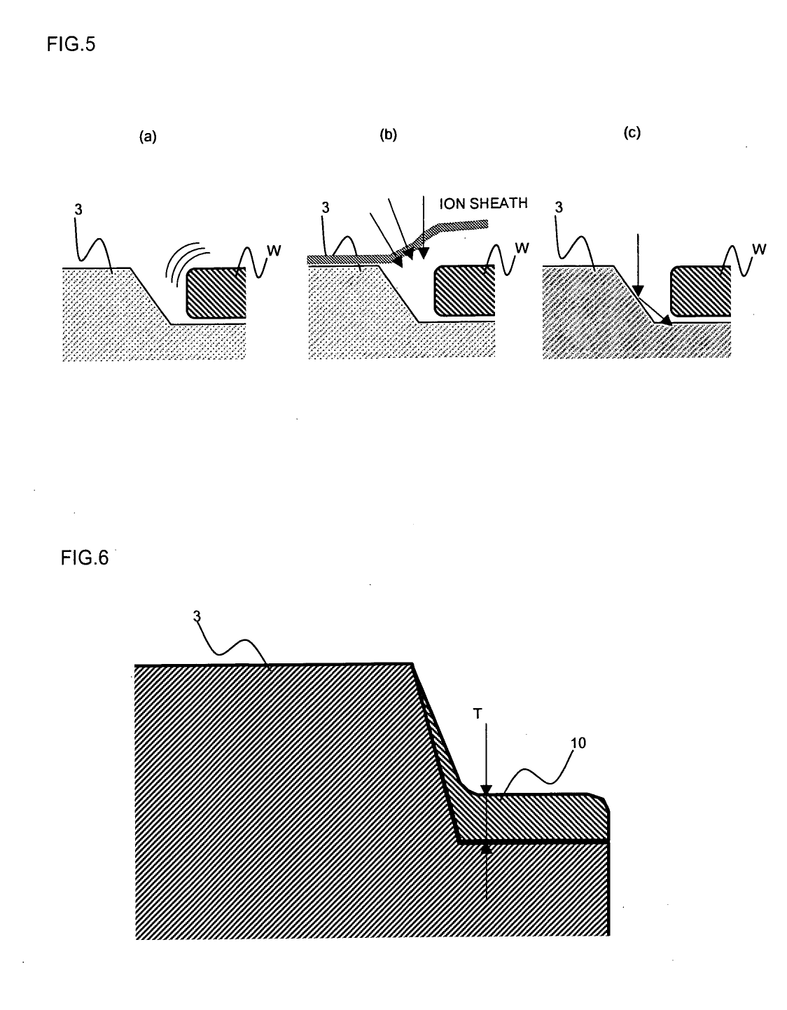

FIG. 6 is a cross-sectional view of an electrode cover 3 according to the present embodiment. The surface of the electrode cover 3 is provided with a Yb₂O₃ coating with a thickness T of 200 micrometers. The sputter rate of Yb₂O₃ is lower than alumina (Al₂O₃) since the elements are heavier. At a glance, it seems desirable to apply a coating 10 of Yb₂O₃ or the like to the whole surface of the electrode cover 3, or to use a sintered body having such material as its main component. However, from processing reasons, it is preferable to coat the material having a low sputter rate and having resistance to plasma to only a limited portion on the cover.

FIG. 7 shows a cross-sectional appearance of the coating formed via spray coating. A spray coating is a method for forming a coating by heating fine particles 11 having a diameter size of approximately 20 micrometers to high temperature and spraying the same onto a target surface at high speed. The thickness of the spray coating to be sprayed on a surface in a single process should preferably be approximately 50 micrometers. If the thickness is smaller than 50 micrometers or greater than 50 micrometers, spray unevenness or defects within the coated layer tend to occur. Therefore, in order to form a thick spray coating, it is necessary to increase the number of scanning operations and to create a multilayered coating, with the thickness of a single coating basically set to 50 micrometers. Further, the adhesion strength of the spray coating is enhanced as the surface roughness 12 increases as shown in FIG. 7, since the anchoring effect is enhanced by surface roughness. Therefore, it is preferable to roughen (provide a treatment to form an arbitrary roughness to) the surface being subjected to spray coating in order to enhance the anchoring effect. Such roughness can be created by grinding and blasting.

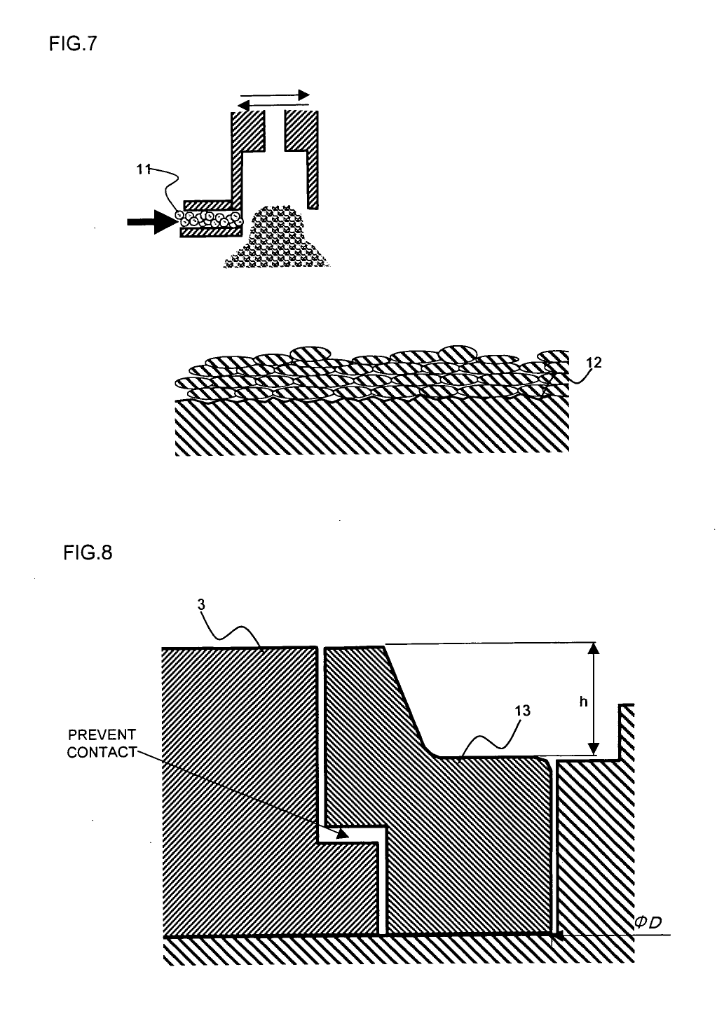

On the other hand, the application of a sintered body is disadvantageous from the point of view of regeneration. For instance, if the whole electrode cover is formed of a sintered body, regeneration thereof becomes difficult. Further, in consideration of the regeneration property, it is possible to form only the portion of the electrode cover corresponding to the wafer edge as a separate member. One example thereof is shown in FIG. 8. As shown in FIG. 8, it is desirable to provide an electrode cover ring 13 formed of a material having resistance to plasma. In this case, since the area corresponds to where the wafer is mounted, it is important to control the dimensions of h and ΦD so as to form a gap that prevents the cover ring from coming into contact with the wafer, and at the same time, the contact surface must be treated appropriately. Moreover, since the electrode cover ring 13 is a very tiny member, the handling thereof requires much care.

From the reasons mentioned above, it is more preferable to provide a coating with a plasma-resistant material to limited areas on the electrode cover from the viewpoints of mass productivity, handling capability and regeneration property.

Next, we will explain the area to be coated. As shown in FIG. 4, the electrode cover 3 serving as the protective cover for the electrode is subjected to intense etching at the portion directly below the wafer edge. Therefore, it is preferable from the viewpoint of the lifetime of the electrode cover to increase the thickness of the portion subjected to intense etching than of the other portions. At this time, the thickness of the spray coating should preferably be at least 50 micrometers or greater from the aforementioned reasons. Furthermore, the area to be coated which is subjected to abrasion or blasting and roughened so as to increase the adhesion strength of the spray coating, should be as small as possible from the viewpoint of mass productivity. In other words, at least the area to be coated with the material having resistance to plasma is determined to be the side closer to the wafer than the tapered area, and the thickness of the portion directly below the wafer edge is increased compared to the other surface areas. Thus, an earth cover having good mass productivity, regeneration property and long lifetime can be achieved.

In a plasma processing apparatuses, anodized aluminum (alumite) or sintered alumina are used widely as materials having resistance to plasma, but the plasma resistance of such materials are not sufficient. Therefore, experiments were performed to evaluate the plasma resistance of alumite as current inner wall material, and Yb₂O₃, Y₂O₃ and YF₃, which were chosen from various possible materials and confirmed that they do not affect the device when applied as inner wall material of the etching apparatus. Further, the plasma resistance of Al₂O₃ formed via sintering of alumite (noncrystalline Al₂O₃), and of Al₂O₃ formed via spraying, were evaluated. In the experiment, Yb₂O₃, Y₂O₃ and YF₃ were coated via spraying.

In the experiment for evaluating the plasma resistance, test pieces, each having a 20 mm-square size, were prepared. Each test piece had alumite or spray coating with a thickness of 0.2 to 0.5 mm formed on the surface of high-purity aluminum with a thickness of 5 mm, and the test piece for the sintered Al₂O₃ material had a thickness of 0.5 mm. In the experiment, the test pieces were adhered to the surface of the wafer with conductive adhesives. Thereafter, the wafer was delivered into the plasma processing apparatus, and was exposed to plasma for a predetermined time. After completing the process, the etching rates were measured and the surface appearances were observed. Though the thickness of the test pieces differ among materials, within the range of the present experiment, the amount of ions entering the test pieces does not depend on the thickness of the material but depend on the resistance of the ion sheath and the high frequency power being loaded thereto, so the thickness of the test pieces does not affect the experiment.

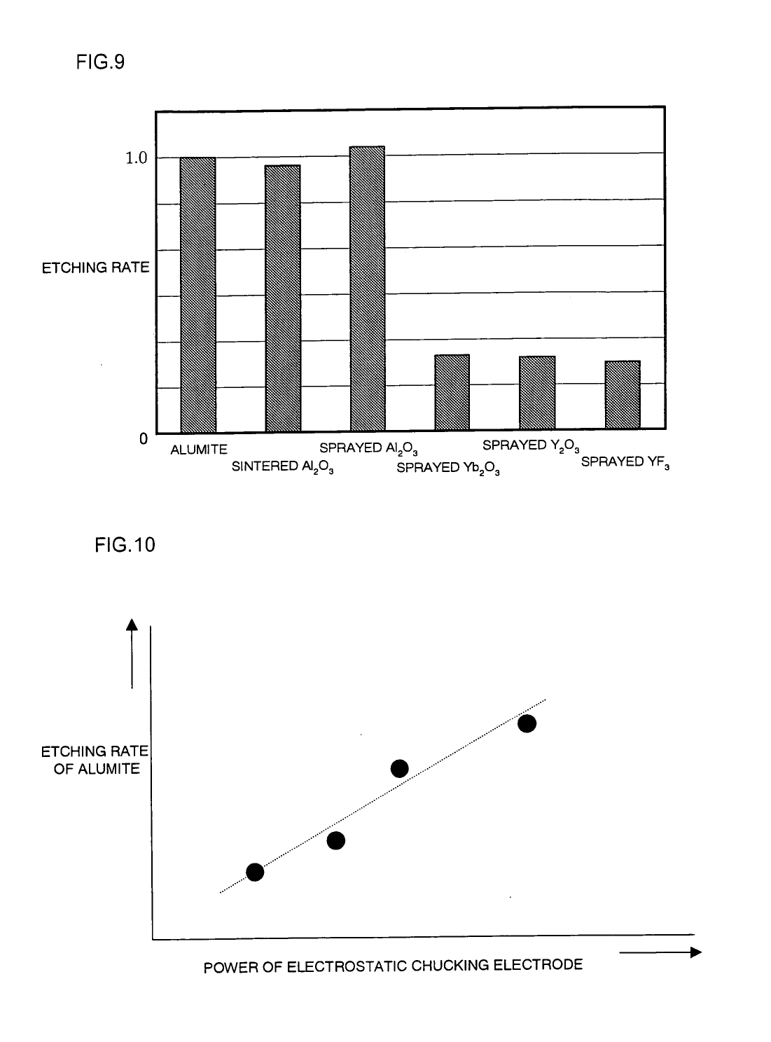

One example of the results of the experiment is illustrated in FIG. 9, which shows the etching rate of the etching performed in chlorine gas plasma. The chart shows the result of the etching operation performed in the etching apparatus shown in FIG. 1 with the pressure set to 0.5 Pa, the Cl₂ flow rate to 150 ml/min, the UHF power to 500 W, and the RF power of electrostatic chucking electrode to 100 W. From the chart shown in FIG. 6, it is recognized that the etching rates of alumite, sintered Al₂O₃ and the sprayed Al₂O₃ were substantially the same with little difference. Further, the etching rates of Y₂O₃, Yb₂O₃ and YF₃ were approximately one-third the etching rates of alumite and Al₂O₃. The surfaces of the test pieces were observed before and after the experiment with an electron microscope, but the appearances of the surfaces were smooth for all the test pieces, and there was no surface with an appearance that indicated the occurrence of a significant chemical reaction. Similar results were achieved through experiments performed under various other conditions using fluorine-based and chlorine-based gases.

FIG. 10 shows the relationship between the RF power of the electrostatic chucking electrode and the etching rate of alumite. The chart shows the variation of the etching rate when the RF power of the electrostatic chucking electrode is varied under the conditions explained in FIG. 9. It is recognized from this chart that the etching rate increases as the RF power increases. This is because the etching rate is determined by the erosion caused by sputtering. Therefore, the reason why the etching rates of alumite, sintered Al₂O₃ and sprayed Al₂O₃ were substantially equal, and why the etching rates of Y₂O₃, Yb₂O₃ and YF₃ were one-third the etching rate of Al₂O₃, was because the etching rate was determined by the erosion caused mainly by sputtering. Thus, it is conceivable that heavier elements are more preferable as the material for forming the wall surface of the processing chamber.

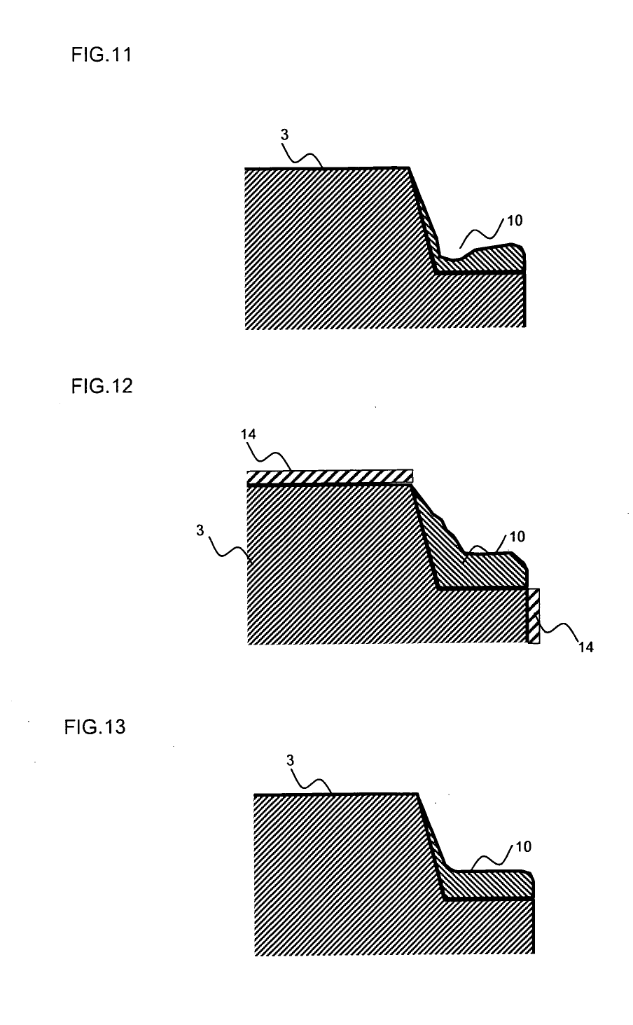

FIGS. 11 through 13 show the steps for regenerating the electrode cover 3. As illustrated in FIG. 11, the surface directly below the wafer edge is chipped by sputtering. The electrode cover having reached either the determined amount of chipping or the determined number of processed wafers is removed from the etching apparatus. Next, the plasma-resistant material on the surface of the removed electrode cover 3 is ground and removed. At this time, while removing the plasma-resistant material, the surface of the electrode cover is roughened so as to provide sufficient anchoring effect for the following spray coating. Next, as shown in FIG. 12, a mask 14 is attached to the cover, and a spray coating process is carried out. At last, as shown in FIG. 13, the spray coating surface is polished to complete the regeneration process.

1. A plasma processing apparatus having a substrate holder disposed in a processing chamber and an electrode cover for protecting a support stage of said substrate holder, for processing a wafer placed on said support stage using a plasma generated in the processing chamber; wherein
at least a surface of said electrode cover that is positioned directly below an edge of the wafer, or at least a surface of said electrode cover that comes into contact with plasma, is coated with a material having resistance to plasma and comprising Y₂O₃, Yb₂O₃ or YF₃, or a mixture thereof, as its main component.

2. The plasma processing apparatus according to claim 1, wherein
the coating having resistance to plasma applied to a portion directly below the edge of the wafer on the surface of said electrode cover is greater in thickness than the coating having resistance to plasma applied to other portions.
